(19) United States
(12) Patent Application Publication
(10) Pub. No.: US 2025/0149372 A1
(43) Pub. Date: May 8, 2025

(54) MICRO HEATER MODULE AND METHOD OF MANUFACTURING THE SAME

(71) Applicant: ASTI GLOBAL INC., TAIWAN, Taichung City (TW)

(72) Inventor: CHIEN-SHOU LIAO, Taichung City (TW)

(21) Appl. No.: 18/939,449

(22) Filed: Nov. 6, 2024

Related U.S. Application Data
(60) Provisional application No. 63/547,769, filed on Nov. 8, 2023.

(51) Int. Cl. H01L 21/683; H01L 23/00; H01L 33/62; H05B 3/28

(52) U.S. Cl. CPC H01L 21/6835; H01L 24/16; H01L 24/81; H05B 3/286; H10H 20/857; H01L 2221/68318; H01L 2221/68354; H01L 2221/68368; H01L 2224/16227; H01L 2224/81005; H01L 2924/12041; H05B 2203/013; H05B 2203/016; H05B 2203/017; H10H 20/0364

(57) ABSTRACT

A micro heater module and a manufacturing method thereof are provided. The micro heater module includes a carrier substrate, an electrode structure and a heating structure. The electrode structure includes a circuit layout layer, multiple electrode structure layers and multiple insulating covering layers. The electrode structure layers are divided into multiple first and second electrode structure layers. The insulating covering layers are divided into multiple first and second insulating covering layers. Each first insulating covering layer partially covers the corresponding first electrode structure layer. Each second insulating covering layer partially covers the corresponding second electrode structure layer. The heating structure includes multiple first and second heating portions. Each first heating portion is electrically connected between two adjacent first electrode structure layers, and each second heating portion is electrically connected between the first electrode structure layer and the second electrode structure layer which are adjacent to each other.

### CROSS-REFERENCE TO RELATED PATENT APPLICATION

This application claims the benefit of priority to the U.S. Provisional Patent Application Ser. No. 63/547,769, filed on Nov. 8, 2023, which application is incorporated herein by reference in its entirety.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a heater module and a manufacturing method thereof, and more particularly to a micro heater module applied for bonding multiple light-emitting diode chips and a method of manufacturing the micro heater module.

### BACKGROUND OF THE DISCLOSURE

In the related art, the semiconductor chips (such as LED chips or other electronic chips) are mostly transferred to the circuit board by using a pick and place machine. However, the efficiency of using the pick and place machine to transfer chips is very low, especially for the transfer of small-sized chips.

### SUMMARY OF THE DISCLOSURE

In response to the above-referenced technical inadequacy, the present disclosure provides a micro heater module and a method of manufacturing the same.

In order to solve the above-mentioned problems, one of the technical aspects adopted by the present disclosure is to provide a micro heater module, which includes a carrier substrate, an electrode structure, a heating structure and an adhesive structure. The electrode structure includes a circuit layout layer disposed on the carrier substrate, a plurality of electrode structure layers disposed on the circuit layout layer, and a plurality of insulating covering layers respectively disposed on the electrode structure layers. The heating structure is configured for covering the electrode structure. The adhesive structure is disposed on the heating structure. The electrode structure layers are divided into a plurality of first electrode structure layers and a plurality of second electrode structure layers, and the insulating covering layers are divided into a plurality of first insulating covering layers and a plurality of second insulating covering layers. Each of the first insulating covering layers partially covers a corresponding one of the first electrode structure layers, so that the corresponding first electrode structure layer has two first exposed end portions contacting the heating structure. Each of the second insulating covering layers partially covers a corresponding one of the second electrode structure layers, so that the corresponding second electrode structure layer has a second exposed end portion contacting the heating structure. The heating structure includes a plurality of first heating portions and a plurality of second heating portions, each of the first heating portions is electrically connected between two adjacent ones of the first electrode structure layers, and each of the second heating portions is electrically connected between the first electrode structure layer and the second electrode structure layer which are adjacent to each other.

In order to solve the above-mentioned problems, another one of the technical aspects adopted by the present disclosure is to provide a micro heater module, which includes a carrier substrate, an electrode structure and a heating structure. The electrode structure includes a circuit layout layer disposed on the carrier substrate, a plurality of electrode structure layers disposed on the circuit layout layer, and a plurality of insulating covering layers respectively disposed on the electrode structure layers. The heating structure is configured for covering the electrode structure. The adhesive structure is disposed on the heating structure. The electrode structure layers are divided into a plurality of first electrode structure layers and a plurality of second electrode structure layers, and the insulating covering layers are divided into a plurality of first insulating covering layers and a plurality of second insulating covering layers. Each of the first insulating covering layers partially covers a corresponding one of the first electrode structure layers, so that the corresponding first electrode structure layer has two first exposed end portions contacting the heating structure. Each of the second insulating covering layers partially covers a corresponding one of the second electrode structure layers, so that the corresponding second electrode structure layer has a second exposed end portion contacting the heating structure. The heating structure includes a plurality of first heating portions and a plurality of second heating portions, each of the first heating portions is electrically connected between two adjacent ones of the first electrode structure layers, and each of the second heating portions is electrically connected between the first electrode structure layer and the second electrode structure layer which are adjacent to each other.

In order to solve the above-mentioned problems, yet another one of the technical aspects adopted by the present disclosure is to provide a method of manufacturing a micro heater module, which includes: providing a carrier substrate; providing an electrode structure on the carrier substrate, in which the electrode structure includes a circuit layout layer disposed on the carrier substrate, a plurality of electrode structure layers disposed on the circuit layout layer, and a plurality of insulating covering layers respectively disposed on the electrode structure layers; and forming a heating structure to cover the electrode structure. The electrode structure layers are divided into a plurality of first electrode structure layers and a plurality of second electrode structure layers, and the insulating covering layers are divided into a plurality of first insulating covering layers and a plurality of second insulating covering layers. Each of the first insulating covering layers partially covers a corresponding one of the first electrode structure layers, so that the corresponding first electrode structure layer has two first exposed end portions contacting the heating structure. Each of the second insulating covering layers partially covers a corresponding one of the second electrode structure layers, so that the corresponding second electrode structure layer has a second exposed end portion contacting the heating structure. The heating structure includes a plurality of first heating portions and a plurality of second heating portions, each of the first heating portions is electrically connected between two adjacent ones of the first electrode structure layers, and each of the second heating portions is electrically connected between the first electrode structure layer and the second electrode structure layer which are adjacent to each other.

In one of the possible or preferred embodiments, each of the first heating portions of the heating structure is configured to cooperate with the two adjacent first exposed end portions of two corresponding ones of the first electrode structure layers to form a first micro heater. Each of the second heating portions of the heating structure is configured to cooperate with the first exposed end portion of a corresponding one of the first electrode structure layers and the second exposed end portion of a corresponding one of the second electrode structure layers to form a second micro heater.

In one of the possible or preferred embodiments, the process of providing the electrode structure on the carrier substrate further includes: forming the circuit layout layer on the carrier substrate; forming the plurality of electrode structure layers on the circuit layout layer; and respectively forming the plurality of insulating covering layers on the electrode structure layers.

In one of the possible or preferred embodiments, the process of providing the electrode structure on the carrier substrate further includes: placing the circuit layout layer carrying the electrode structure layers on the carrier substrate; and respectively forming the insulating covering layers on the electrode structure layers.

In one of the possible or preferred embodiments, after the process of forming the heating structure to cover the electrode structure, the method of the micro heater module further includes: forming an adhesive structure on the heating structure.

Therefore, in the a micro heater module and a method of manufacturing the same provided by the present disclosure, by virtue of “the electrode structure including a circuit layout layer disposed on the carrier substrate, a plurality of electrode structure layers disposed on the circuit layout layer, and a plurality of insulating covering layers respectively disposed on the electrode structure layers,” “each of the first insulating covering layers partially covering a corresponding one of the first electrode structure layers, so that the corresponding first electrode structure layer has two first exposed end portions contacting the heating structure,” “each of the second insulating covering layers partially covering a corresponding one of the second electrode structure layers, so that the corresponding second electrode structure layer has a second exposed end portion contacting the heating structure,” “each of the first heating portions being electrically connected between two adjacent ones of the first electrode structure layers” and “each of the second heating portions being electrically connected between the first electrode structure layer and the second electrode structure layer which are adjacent to each other,” so that the plurality of first heating portions and the plurality of second heating portions can be configured to bond the plurality of light-emitting diode chips on a predetermined circuit substrate through heating (that is to say, the plurality of light-emitting diode chips can be bonded on the predetermined circuit substrate through the heat generated by the plurality of first heating portions and the plurality of second heating portions).

Furthermore, in the method of manufacturing the micro heater module provided by the present disclosure, by virtue of “the electrode structure including a circuit layout layer disposed on the carrier substrate, a plurality of electrode structure layers disposed on the circuit layout layer, and a plurality of insulating covering layers respectively disposed on the electrode structure layers,” “each of the first insulating covering layers partially covering a corresponding one of the first electrode structure layers, so that the corresponding first electrode structure layer has two first exposed end portions contacting the heating structure,” “each of the second insulating covering layers partially covering a corresponding one of the second electrode structure layers, so that the corresponding second electrode structure layer has a second exposed end portion contacting the heating structure,” “each of the first heating portions being electrically connected between two adjacent ones of the first electrode structure layers” and “each of the second heating portions being electrically connected between the first electrode structure layer and the second electrode structure layer which are adjacent to each other,” so that the plurality of first heating portions and the plurality of second heating portions can be configured to bond the plurality of light-emitting diode chips on a predetermined circuit substrate through heating (that is to say, the plurality of light-emitting diode chips can be bonded on the predetermined circuit substrate through the heat generated by the plurality of first heating portions and the plurality of second heating portions).

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a flow chart of a method of manufacturing a micro heater module provided by the present disclosure;

FIG. 2 is a schematic view of step S1020 of the method of manufacturing the micro heater module provided by the present disclosure;

FIG. 3 is a schematic view of step S1022 and step S1024 of the method of manufacturing the micro heater module provided by the present disclosure;

FIG. 4 is a schematic view of step S1026 of the method of manufacturing the micro heater module provided by the present disclosure;

FIG. 5 is a schematic view of step S102 and step S1028 of the method of manufacturing the micro heater module provided by the present disclosure;

FIG. 6 is a schematic view of step S104 of the method of manufacturing the micro heater module provided by the present disclosure;

FIG. 7 is a schematic view of step S106 of the method of manufacturing the micro heater module provided by the present disclosure and a schematic view of the micro heater module provided by the present disclosure;

FIG. 8 is a schematic view of the micro heater module provided by the present disclosure using an adhesive structure to adhere and carry a plurality of light-emitting diode chips;

FIG. 9 is a schematic view of the micro heater module provided by the present disclosure using a plurality of first micro heaters and a plurality of second micro heaters to bond the plurality of light emitting diode chips on a predetermined circuit substrate through heating; and

FIG. 10 is a schematic view of the micro heater module provided by the present disclosure being separated from the plurality of light emitting diode chips that have been bonded on the predetermined circuit substrate.

### DETAILED DESCRIPTION OF THE EXEMPLARY EMBODIMENTS

The present disclosure is more particularly described in the following embodiments and examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

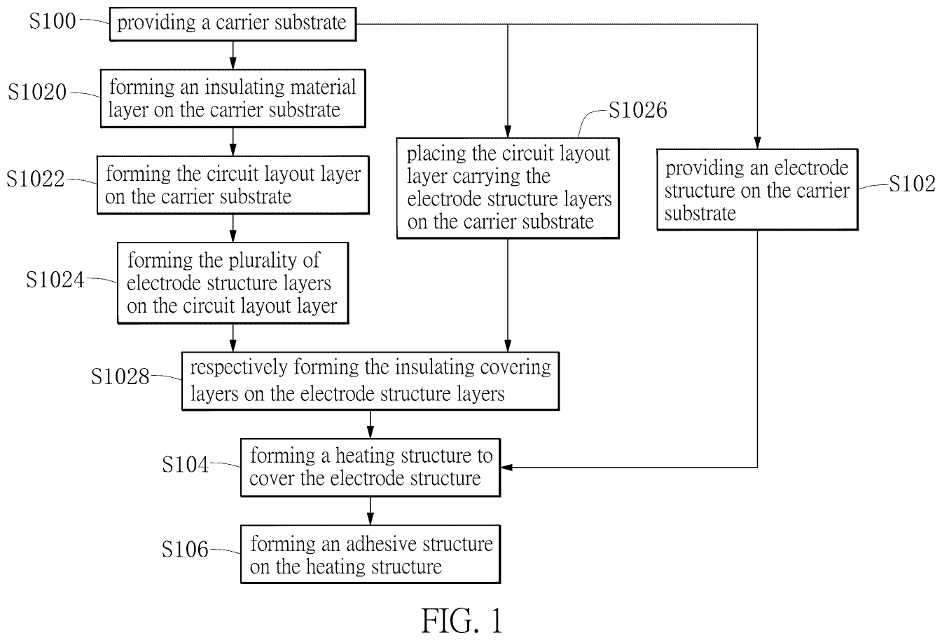

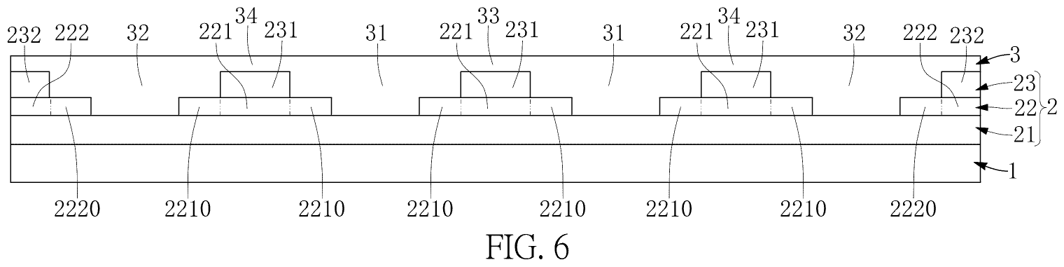

Referring to FIG. 1 to FIG. 7, the present disclosure provides a method of manufacturing a micro heater module M, which may include the following processes: firstly, referring to FIG. 1 to FIG. 5, providing a carrier substrate 1 (step S100), and providing an electrode structure 2 on the carrier substrate 1 (step S102), in which the electrode structure 2 may include a circuit layout layer 21 disposed on the carrier substrate 1, a plurality of electrode structure layers 22 disposed on the circuit layout layer 21, and a plurality of insulating covering layers 23 respectively disposed on the electrode structure layers 22; next, referring to FIG. 1 and FIG. 6, forming a heating structure 3 to cover the electrode structure 2 (step S104). More particularly, the electrode structure layers 22 can be divided into a plurality of first electrode structure layers 221 and a plurality of second electrode structure layers 222, and the insulating covering layers 23 can be divided into a plurality of first insulating covering layers 231 and a plurality of second insulating covering layers 232. Furthermore, each of the first insulating covering layers 231 can partially cover a corresponding one of the first electrode structure layers 221, so that the corresponding first electrode structure layer 221 has two first exposed end portions 2210 directly contacting the heating structure 3. Moreover, each of the second insulating covering layers 232 can partially cover a corresponding one of the second electrode structure layers 222, so that the corresponding second electrode structure layer 222 has a second exposed end portion 2220 directly contacting the heating structure 3. In addition, the heating structure 3 may include a plurality of first heating portions 31 and a plurality of second heating portions 32, each of the first heating portions 31 can be electrically connected between two adjacent ones of the first electrode structure layers 221, and each of the second heating portions 32 can be electrically connected between the first electrode structure layer 221 and the second electrode structure layer 222 which are adjacent to each other.

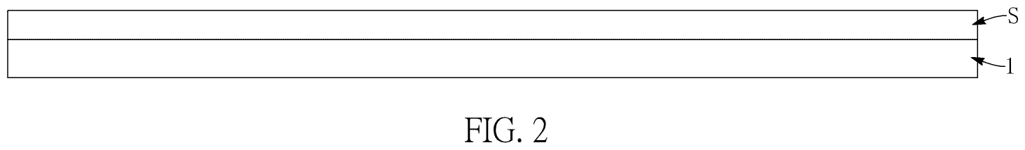

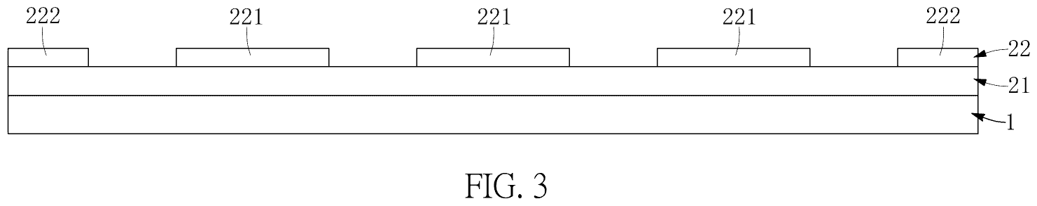

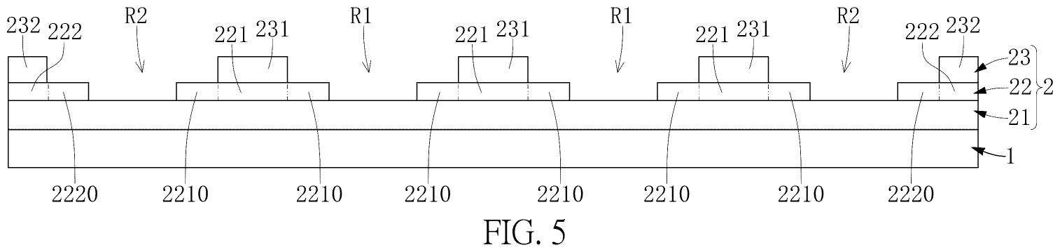

For example, referring to FIG. 1, FIG. 2, FIG. 3 and FIG. 5, in one of the feasible embodiments, the process (step S102) of providing the electrode structure 2 on the carrier substrate 1 may further include: firstly, referring to FIG. 1, FIG. 2 and FIG. 3, forming an insulating material layer S (such as a polymer material layer or any type of insulating material layer) on the carrier substrate 1 (step S1020), then forming the circuit layout layer 21 on the carrier substrate 1 through a semiconductor process (such as exposure, development, etching, evaporation) or a non-semiconductor process (step S1022), then forming the plurality of electrode structure layers 22 (including the plurality of first electrode structure layers 221 and the plurality of second electrode structure layers 222) on the circuit layout layer 21 through a semiconductor process (such as exposure, development, etching, evaporation) or a non-semiconductor process (step S1024); Next, referring to FIG. 1 and FIG. 5, respectively forming the plurality of insulating covering layers 23 (including the plurality of first insulating covering layers 231 and the plurality of second insulating covering layers 232) on the electrode structure layers 22 (step S1028). However, the aforementioned details are disclosed for exemplary purposes only, and are not meant to limit the scope of the present disclosure.

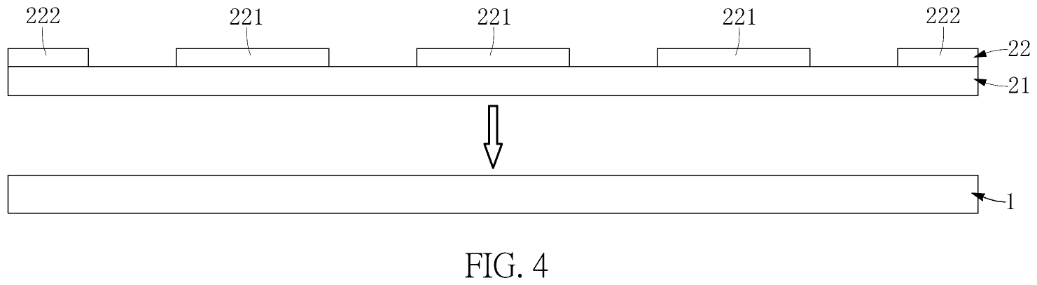

For example, referring to FIG. 1, FIG. 4 and FIG. 5, in one of the feasible embodiments, the process (step S102) of providing the electrode structure 2 on the carrier substrate 1 may further include: firstly, referring to FIG. 1 and FIG. 4, placing the circuit layout layer 21 carrying the electrode structure layers 22 (including the plurality of first electrode structure layers 221 and the plurality of second electrode structure layers 222) on the carrier substrate 1 (step S1026); next, referring to FIG. 1 and FIG. 5, respectively forming the insulating covering layers 23 (including the plurality of first insulating covering layers 231 and the plurality of second insulating covering layers 232) on the electrode structure layers 22 (step S1028). However, the aforementioned details are disclosed for exemplary purposes only, and are not meant to limit the scope of the present disclosure.

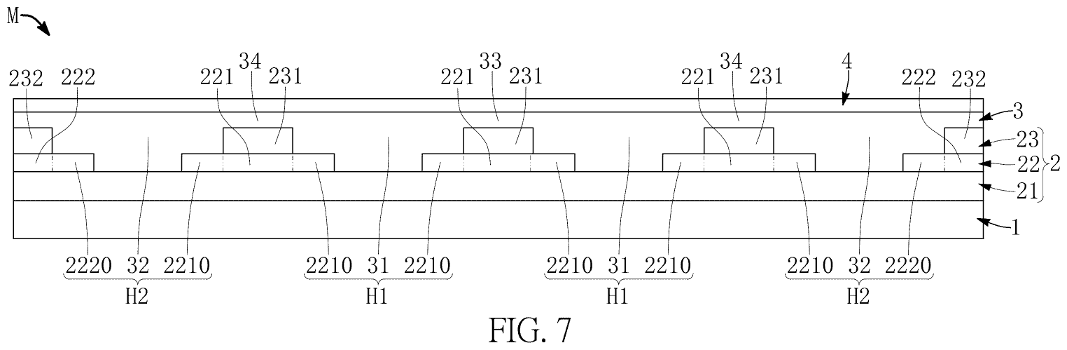

For example, referring to FIG. 1 and FIG. 7, in one of the feasible embodiments, after the process (step S104) of forming the heating structure 3 to cover the electrode structure 2, the method of the micro heater module M may further include: forming an adhesive structure 4 on the heating structure 3 (step S106). However, the aforementioned details are disclosed for exemplary purposes only, and are not meant to limit the scope of the present disclosure.

It should be noted that as shown in FIG. 7, the present disclosure further provides a micro heater module M, which may include a carrier substrate 1, an electrode structure 2, a heating structure 3 and an adhesive structure 4. The electrode structure 2 may include a circuit layout layer 21 disposed on the carrier substrate 1, a plurality of electrode structure layers 22 disposed on the circuit layout layer 21, and a plurality of insulating covering layers 23 respectively disposed on the electrode structure layers 22. The heating structure 3 can be configured for covering the electrode structure 2, and the adhesive structure 4 is disposed on the heating structure 3. More particularly, the electrode structure layers 22 can be divided into a plurality of first electrode structure layers 221 and a plurality of second electrode structure layers 222, and the insulating covering layers 23 can be divided into a plurality of first insulating covering layers 231 and a plurality of second insulating covering layers 232. Furthermore, each of the first insulating covering layers 231 can partially cover a corresponding one of the first electrode structure layers 221, so that the corresponding first electrode structure layer 221 has two first exposed end portions 2210 for directly contacting the heating structure 3. Moreover, each of the second insulating covering layers 232 can partially cover a corresponding one of the second electrode structure layers 222, so that the corresponding second electrode structure layer 222 has a second exposed end portion 2220 for directly contacting the heating structure 3.

For example, referring to FIG. 5 and FIG. 7, the electrode structure 2 has a plurality of first accommodation areas R1 (or first receiving areas) and a plurality of second accommodation areas R2 (or second receiving areas), the first accommodation areas R1 can be configured to respectively accommodate the first heating portions 31 of the heating structure 3, and the second accommodation areas R2 can be configured to respectively accommodate the second heating portions 32 of the heating structure 3. More particularly, each of the first accommodation areas R1 can be located between two adjacent ones of the first electrode structure layers 221 and between two adjacent ones of the first insulating covering layers 231 for accommodating a corresponding one of the first heating portions 31. Furthermore, each of the second accommodation areas R2 can be located between the first electrode structure layer 221 and the second electrode structure layer 222 which are adjacent to each other and between the first insulating covering layer 231 and the second insulating covering layer 232 which are adjacent to each other for accommodating a corresponding one of the second heating portions 32. It should be noted that the two first exposed end portions 2210 of the first electrode structure layer 221 can be respectively located at two opposite ends of the first electrode structure layer 221, and the second exposed end portion 2220 of the second electrode structure layer 222 can be located at one end of the second electrode structure layer 222. Moreover, the insulating covering layers 23 (including the plurality of first insulating covering layers 231 and the plurality of second insulating covering layers 232) can respectively and partially cover the electrode structure layers 22 (including the plurality of first electrode structure layers 221 and the plurality of second electrode structure layers 222). In addition, according to different requirements, the circuit layout layer 21 of the electrode structure 2 can be configured as a polyimide film (PI film) with a circuit layout, a flexible printed circuit board (FPC) with a circuit layout, an FR4 printed circuit with a circuit layout, or any kind of circuit layout carrier layer, each electrode structure layer 22 of the electrode structure 2 can be configured as any kind of conductive material layer, and each insulating covering layer 23 of the electrode structure 2 can be configured as a silicone layer, an epoxy resin layer or any kind of insulating material layer. However, the aforementioned details are disclosed for exemplary purposes only, and are not meant to limit the scope of the present disclosure.

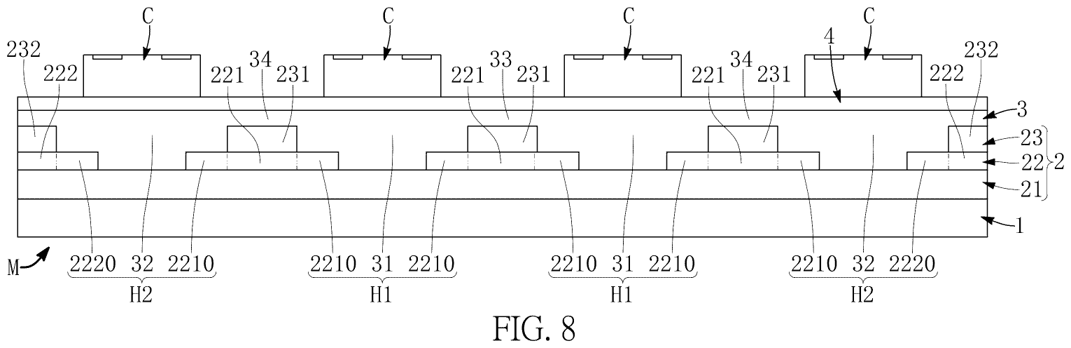

For example, as shown in FIG. 7, the heating structure 3 may include a plurality of first heating portions 31 and a plurality of second heating portions 32, each of the first heating portions 31 can be electrically connected between two adjacent ones of the first electrode structure layers 221, and each of the second heating portions 32 can be electrically connected between the first electrode structure layer 221 and the second electrode structure layer 222 which are adjacent to each other. More particularly, the heating structure 3 may further include a plurality of first connection portions 33 (the present disclosure is illustrated in the drawings by taking a first connecting portion 33 as an example) and a plurality of second connection portions 34, each of the first connection portions 33 can be electrically connected between two adjacent ones of the first heating portions 31, and each of the second connection portions 34 can be electrically connected between the first heating portion 31 and the second heating portion 32 which are adjacent to each other. It should be noted that the heating structure 3 can be configured as a high-resistance conductive film (such as a graphite layer, an indium tin oxide layer or any kind of high resistance conductive film), and the first heating portions 31 and the second heating portions 32 of the heating structure 3 can be arranged corresponding to a predetermined pixel layout (such as corresponding to the positions of the LED chips that are arranged as a predetermined pixel array). In addition, the adhesive structure 4 can be configured as an adhesive material layer or a double-sided adhesive layer, and the adhesive structure 4 can be configured for adhering a plurality of light-emitting diode chips C (as shown in FIG. 8) or any kind of semiconductor chip. However, the aforementioned details are disclosed for exemplary purposes only, and are not meant to limit the scope of the present disclosure.

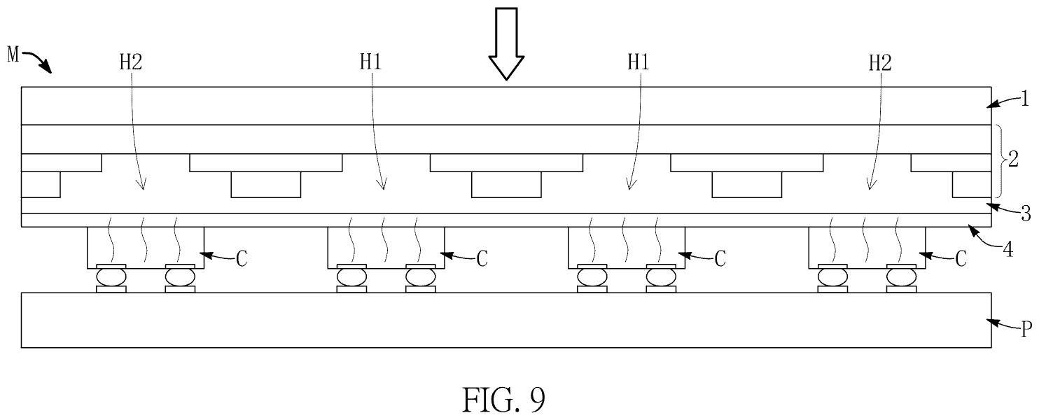

For example, referring to FIG. 8 and FIG. 9, when the adhesion structure 4 can be configured to adhere a plurality of light-emitting diode chips C (such as micro LED chips, mini LED chips or any kind of LED chips), the plurality of first heating portions 31 and the plurality of second heating portions 32 of the heating structure 3 can be arranged corresponding to a predetermined pixel arrangement of the plurality of light-emitting diode chips C, so that the plurality of first heating portions 31 and the plurality of second heating portions 32 of the heating structure 3 can respectively and correspondingly heat the plurality of light-emitting diode chips C (especially heating at least two solder pads or at least two solder balls of each light-emitting diode chip C), thereby simultaneously bonding the corresponding light-emitting diode chips C on the predetermined circuit substrate P. More particularly, each of the first heating portions 31 of the heating structure 3 can be configured to cooperate with the two adjacent first exposed end portions 2210 of two corresponding (or two adjacent) ones of the first electrode structure layers 221 to form a first micro heater H1 (that is to say, each first micro heater H1 at least includes a first heating portion 31 and two adjacent first exposed end portions 2210), so that each first heating portion 31 can be electrically heated by the two corresponding first electrode structure layers 221 (that is to say, each first heating portion 31 can generate thermal energy by supplying power to the two corresponding first electrode structure layers 221), thereby bonding the corresponding light-emitting diode chip C on the predetermined circuit substrate P. In addition, each of the second heating portions 32 of the heating structure 3 can be configured to cooperate with the first exposed end portion 2210 of a corresponding (or an adjacent) one of the first electrode structure layers 221 and the second exposed end portion 2220 of a corresponding one (or an adjacent) of the second electrode structure layers 222 to form a second micro heater H2 (that is to say, each second micro heater H2 at least includes the second heating portion 32, and the first exposed end portion 2210 and the second exposed end portion 2220 which are adjacent to each other), so that each second heating portion 32 can be electrically heated by the corresponding first electrode structure layer 221 and the corresponding second electrode structure layer 222 (that is to say, each second heating portion 32 can generate thermal energy by supplying power to the first exposed end portion 2210 and the second exposed end portion 2220 which are adjacent to each other), thereby bonding the corresponding light-emitting diode chip C on the predetermined circuit substrate P. However, the aforementioned details are disclosed for exemplary purposes only, and are not meant to limit the scope of the present disclosure.

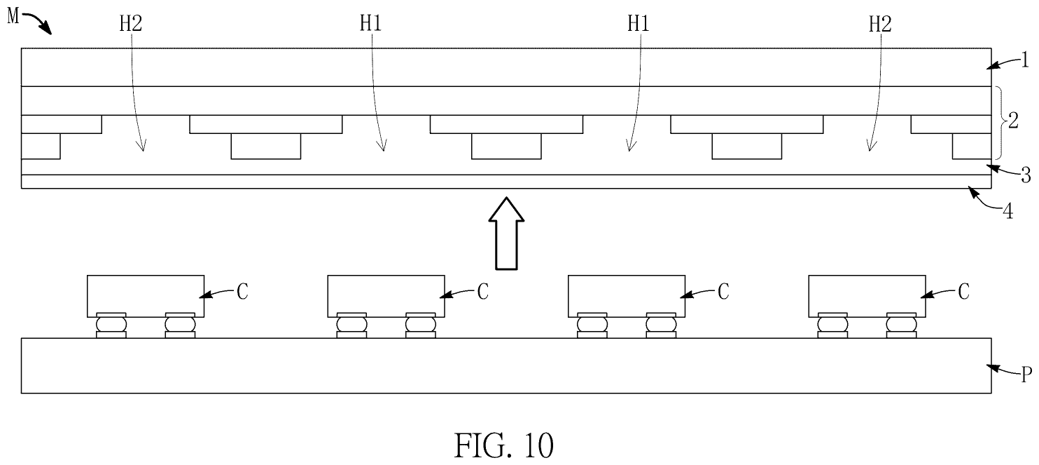

It should be noted that referring to FIG. 9 and FIG. 10, after the light-emitting diode chips C are simultaneously bonded on the predetermined circuit substrate P through heating by the plurality of first heating portions 31 and the plurality of second heating portions 32 (as shown in FIG. 9), the bonding strength between the light-emitting diode chip C and the corresponding plurality of solder balls is greater than the bonding strength between the light-emitting diode chip C and the adhesion structure 4 of the micro heater module M, so that the micro heater module M can be easily separated from the plurality of light emitting diode chips C (as shown in FIG. 10). That is to say, as shown in FIG. 10, after the micro heater module M is detached from the plurality of light-emitting diode chips C, the plurality of light-emitting diode chips C can still be firmly bonded or fixed on the predetermined circuit substrate P.

### Beneficial Effects of the Embodiments

In conclusion, in the a micro heater module M and a method of manufacturing the same provided by the present disclosure, by virtue of “the electrode structure 2 including a circuit layout layer 21 disposed on the carrier substrate 1, a plurality of electrode structure layers 22 disposed on the circuit layout layer 21, and a plurality of insulating covering layers 23 respectively disposed on the electrode structure layers 22,” “each of the first insulating covering layers 231 partially covering a corresponding one of the first electrode structure layers 221, so that the corresponding first electrode structure layer 221 has two first exposed end portions 2210 contacting the heating structure 3,” “each of the second insulating covering layers 232 partially covering a corresponding one of the second electrode structure layers 222, so that the corresponding second electrode structure layer 222 has a second exposed end portion 2220 contacting the heating structure 3,” “each of the first heating portions 31 being electrically connected between two adjacent ones of the first electrode structure layers 221” and “each of the second heating portions 32 being electrically connected between the first electrode structure layer 221 and the second electrode structure layer 222 which are adjacent to each other,” so that the plurality of first heating portions 31 and the plurality of second heating portions 32 can be configured to bond the plurality of light-emitting diode chips C on a predetermined circuit substrate P through heating (that is to say, the plurality of light-emitting diode chips C can be bonded on the predetermined circuit substrate P through the heat generated by the plurality of first heating portions 31 and the plurality of second heating portions 32).

Furthermore, in the method of manufacturing the micro heater module M provided by the present disclosure, by virtue of “the electrode structure 2 including a circuit layout layer 21 disposed on the carrier substrate 1, a plurality of electrode structure layers 22 disposed on the circuit layout layer 21, and a plurality of insulating covering layers 23 respectively disposed on the electrode structure layers 22,” “each of the first insulating covering layers 231 partially covering a corresponding one of the first electrode structure layers 221, so that the corresponding first electrode structure layer 221 has two first exposed end portions 2210 contacting the heating structure 3,” “each of the second insulating covering layers 232 partially covering a corresponding one of the second electrode structure layers 222, so that the corresponding second electrode structure layer 222 has a second exposed end portion 2220 contacting the heating structure 3,” “each of the first heating portions 31 being electrically connected between two adjacent ones of the first electrode structure layers 221” and “each of the second heating portions 32 being electrically connected between the first electrode structure layer 221 and the second electrode structure layer 222 which are adjacent to each other,” so that the plurality of first heating portions 31 and the plurality of second heating portions 32 can be configured to bond the plurality of light-emitting diode chips C on a predetermined circuit substrate P through heating (that is to say, the plurality of light-emitting diode chips C can be bonded on the predetermined circuit substrate P through the heat generated by the plurality of first heating portions 31 and the plurality of second heating portions 32).

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A micro heater module, comprising:
a carrier substrate;
an electrode structure including a circuit layout layer disposed on the carrier substrate, a plurality of electrode structure layers disposed on the circuit layout layer, and a plurality of insulating covering layers respectively disposed on the electrode structure layers;
a heating structure covering the electrode structure; and
an adhesive structure disposed on the heating structure;
wherein the electrode structure layers are divided into a plurality of first electrode structure layers and a plurality of second electrode structure layers, and the insulating covering layers are divided into a plurality of first insulating covering layers and a plurality of second insulating covering layers;
wherein each of the first insulating covering layers partially covers a corresponding one of the first electrode structure layers, so that the corresponding first electrode structure layer has two first exposed end portions contacting the heating structure;
wherein each of the second insulating covering layers partially covers a corresponding one of the second electrode structure layers, so that the corresponding second electrode structure layer has a second exposed end portion contacting the heating structure;
wherein the heating structure includes a plurality of first heating portions and a plurality of second heating portions, each of the first heating portions is electrically connected between two adjacent ones of the first electrode structure layers, and each of the second heating portions is electrically connected between the first electrode structure layer and the second electrode structure layer which are adjacent to each other.

2. The micro heater module according to claim 1,
wherein the circuit layout layer of the electrode structure is configured as a polyimide film, a flexible printed circuit board or an FR4 printed circuit board that has a circuit layout disposed thereon;
wherein the insulating covering layers respectively and partially cover the electrode structure layers, and each of the insulating covering layers is configured as a silicone layer or an epoxy resin layer;
wherein the electrode structure has a plurality of first accommodation areas and a plurality of second accommodation areas, the first accommodation areas are configured to respectively accommodate the first heating portions of the heating structure, and the second accommodation areas are configured to respectively accommodate the second heating portions of the heating structure;
wherein each of the first accommodation areas is located between two adjacent ones of the first electrode structure layers and between two adjacent ones of the first insulating covering layers for accommodating a corresponding one of the first heating portions;
wherein each of the second accommodation areas is located between the first electrode structure layer and the second electrode structure layer which are adjacent to each other and between the first insulating covering layer and the second insulating covering layer which are adjacent to each other for accommodating a corresponding one of the second heating portions;
wherein the two first exposed end portions of the first electrode structure layer are respectively located at two opposite ends of the first electrode structure layer, and the second exposed end portion of the second electrode structure layer is located at one end of the second electrode structure layer;
wherein each of the first heating portions of the heating structure is configured to cooperate with the two adjacent first exposed end portions of two corresponding ones of the first electrode structure layers to form a first micro heater;
wherein each of the second heating portions of the heating structure is configured to cooperate with the first exposed end portion of a corresponding one of the first electrode structure layers and the second exposed end portion of a corresponding one of the second electrode structure layers to form a second micro heater.

3. The micro heater module according to claim 1,
wherein the heating structure further includes a plurality of first connection portions and a plurality of second connection portions, each of the first connection portions is electrically connected between two adjacent ones of the first heating portions, and each of the second connection portions is electrically connected between the first heating portion and the second heating portion which are adjacent to each other;
wherein the heating structure is configured as a high-resistance conductive film, and the high-resistance conductive film is a graphite layer or an indium tin oxide layer;
wherein the adhesive structure is configured as an adhesive material layer or a double-sided adhesive layer;
wherein the adhesive structure is configured for adhering a plurality of light-emitting diode chips;
wherein the first heating portions and the second heating portions of the heating structure are arranged corresponding to a predetermined pixel layout;
wherein each of the first heating portions of the heating structure is configured to cooperate with the two adjacent first exposed end portions of two corresponding ones of the first electrode structure layers to form a first micro heater;
wherein each of the second heating portions of the heating structure is configured to cooperate with the first exposed end portion of a corresponding one of the first electrode structure layers and the second exposed end portion of a corresponding one of the second electrode structure layers to form a second micro heater.

4. A micro heater module, comprising:
a carrier substrate;
an electrode structure including a circuit layout layer disposed on the carrier substrate, a plurality of electrode structure layers disposed on the circuit layout layer, and a plurality of insulating covering layers respectively disposed on the electrode structure layers; and
a heating structure covering the electrode structure;
wherein the electrode structure layers are divided into a plurality of first electrode structure layers and a plurality of second electrode structure layers, and the insulating covering layers are divided into a plurality of first insulating covering layers and a plurality of second insulating covering layers;
wherein each of the first insulating covering layers partially covers a corresponding one of the first electrode structure layers, so that the corresponding first electrode structure layer has two first exposed end portions contacting the heating structure;
wherein each of the second insulating covering layers partially covers a corresponding one of the second electrode structure layers, so that the corresponding second electrode structure layer has a second exposed end portion contacting the heating structure;
wherein the heating structure includes a plurality of first heating portions and a plurality of second heating portions, each of the first heating portions is electrically connected between two adjacent ones of the first electrode structure layers, and each of the second heating portions is electrically connected between the first electrode structure layer and the second electrode structure layer which are adjacent to each other.

5. The micro heater module according to claim 4,
wherein the circuit layout layer of the electrode structure is configured as a polyimide film, a flexible printed circuit board or an FR4 printed circuit board that has a circuit layout disposed thereon;
wherein the insulating covering layers respectively and partially cover the electrode structure layers, and each of the insulating covering layers is configured as a silicone layer or an epoxy resin layer;
wherein the electrode structure has a plurality of first accommodation areas and a plurality of second accommodation areas, the first accommodation areas are configured to respectively accommodate the first heating portions of the heating structure, and the second accommodation areas are configured to respectively accommodate the second heating portions of the heating structure;
wherein each of the first accommodation areas is located between two adjacent ones of the first electrode structure layers and between two adjacent ones of the first insulating covering layers for accommodating a corresponding one of the first heating portions;
wherein each of the second accommodation areas is located between the first electrode structure layer and the second electrode structure layer which are adjacent to each other and between the first insulating covering layer and the second insulating covering layer which are adjacent to each other for accommodating a corresponding one of the second heating portions;
wherein the two first exposed end portions of the first electrode structure layer are respectively located at two opposite ends of the first electrode structure layer, and the second exposed end portion of the second electrode structure layer is located at one end of the second electrode structure layer;
wherein each of the first heating portions of the heating structure is configured to cooperate with the two adjacent first exposed end portions of two corresponding ones of the first electrode structure layers to form a first micro heater;
wherein each of the second heating portions of the heating structure is configured to cooperate with the first exposed end portion of a corresponding one of the first electrode structure layers and the second exposed end portion of a corresponding one of the second electrode structure layers to form a second micro heater.

6. The micro heater module according to claim 4,
wherein the heating structure further includes a plurality of first connection portions and a plurality of second connection portions, each of the first connection portions is electrically connected between two adjacent ones of the first heating portions, and each of the second connection portions is electrically connected between the first heating portion and the second heating portion which are adjacent to each other;
wherein the heating structure is configured as a high-resistance conductive film, and the high-resistance conductive film is a graphite layer or an indium tin oxide layer;
wherein the first heating portions and the second heating portions of the heating structure are arranged corresponding to a predetermined pixel layout;
wherein each of the first heating portions of the heating structure is configured to cooperate with the two adjacent first exposed end portions of two corresponding ones of the first electrode structure layers to form a first micro heater;
wherein each of the second heating portions of the heating structure is configured to cooperate with the first exposed end portion of a corresponding one of the first electrode structure layers and the second exposed end portion of a corresponding one of the second electrode structure layers to form a second micro heater.

7. A method of manufacturing a micro heater module, comprising:
providing a carrier substrate;
providing an electrode structure on the carrier substrate, wherein the electrode structure includes a circuit layout layer disposed on the carrier substrate, a plurality of electrode structure layers disposed on the circuit layout layer, and a plurality of insulating covering layers respectively disposed on the electrode structure layers; and
forming a heating structure to cover the electrode structure;
wherein the electrode structure layers are divided into a plurality of first electrode structure layers and a plurality of second electrode structure layers, and the insulating covering layers are divided into a plurality of first insulating covering layers and a plurality of second insulating covering layers;
wherein each of the first insulating covering layers partially covers a corresponding one of the first electrode structure layers, so that the corresponding first electrode structure layer has two first exposed end portions contacting the heating structure;
wherein each of the second insulating covering layers partially covers a corresponding one of the second electrode structure layers, so that the corresponding second electrode structure layer has a second exposed end portion contacting the heating structure;
wherein the heating structure includes a plurality of first heating portions and a plurality of second heating portions, each of the first heating portions is electrically connected between two adjacent ones of the first electrode structure layers, and each of the second heating portions is electrically connected between the first electrode structure layer and the second electrode structure layer which are adjacent to each other.

8. The method according to claim 7, wherein the process of providing the electrode structure on the carrier substrate further includes:
forming the circuit layout layer on the carrier substrate;
forming the plurality of electrode structure layers on the circuit layout layer; and
respectively forming the plurality of insulating covering layers on the electrode structure layers;
wherein the electrode structure has a plurality of first accommodation areas and a plurality of second accommodation areas, the first accommodation areas are configured to respectively accommodate the first heating portions of the heating structure, and the second accommodation areas are configured to respectively accommodate the second heating portions of the heating structure;
wherein each of the first accommodation areas is located between two adjacent ones of the first electrode structure layers and between two adjacent ones of the first insulating covering layers for accommodating a corresponding one of the first heating portions;
wherein each of the second accommodation areas is located between the first electrode structure layer and the second electrode structure layer which are adjacent to each other and between the first insulating covering layer and the second insulating covering layer which are adjacent to each other for accommodating a corresponding one of the second heating portions;
wherein the heating structure further includes a plurality of first connection portions and a plurality of second connection portions, each of the first connection portions is electrically connected between two adjacent ones of the first heating portions, and each of the second connection portions is electrically connected between the first heating portion and the second heating portion which are adjacent to each other;
wherein each of the first heating portions of the heating structure is configured to cooperate with the two adjacent first exposed end portions of two corresponding ones of the first electrode structure layers to form a first micro heater;
wherein each of the second heating portions of the heating structure is configured to cooperate with the first exposed end portion of a corresponding one of the first electrode structure layers and the second exposed end portion of a corresponding one of the second electrode structure layers to form a second micro heater.

9. The method according to claim 7, wherein the process of providing the electrode structure on the carrier substrate further includes:
placing the circuit layout layer carrying the electrode structure layers on the carrier substrate; and
respectively forming the insulating covering layers on the electrode structure layers;
wherein the electrode structure has a plurality of first accommodation areas and a plurality of second accommodation areas, the first accommodation areas are configured to respectively accommodate the first heating portions of the heating structure, and the second accommodation areas are configured to respectively accommodate the second heating portions of the heating structure;
wherein each of the first accommodation areas is located between two adjacent ones of the first electrode structure layers and between two adjacent ones of the first insulating covering layers for accommodating a corresponding one of the first heating portions;
wherein each of the second accommodation areas is located between the first electrode structure layer and the second electrode structure layer which are adjacent to each other and between the first insulating covering layer and the second insulating covering layer which are adjacent to each other for accommodating a corresponding one of the second heating portions;
wherein the heating structure further includes a plurality of first connection portions and a plurality of second connection portions, each of the first connection portions is electrically connected between two adjacent ones of the first heating portions, and each of the second connection portions is electrically connected between the first heating portion and the second heating portion which are adjacent to each other;
wherein each of the first heating portions of the heating structure is configured to cooperate with the two adjacent first exposed end portions of two corresponding ones of the first electrode structure layers to form a first micro heater;
wherein each of the second heating portions of the heating structure is configured to cooperate with the first exposed end portion of a corresponding one of the first electrode structure layers and the second exposed end portion of a corresponding one of the second electrode structure layers to form a second micro heater.

10. The method according to claim 7,
wherein, after the process of forming the heating structure to cover the electrode structure, the method of the micro heater module further includes: forming an adhesive structure on the heating structure;
wherein the electrode structure has a plurality of first accommodation areas and a plurality of second accommodation areas, the first accommodation areas are configured to respectively accommodate the first heating portions of the heating structure, and the second accommodation areas are configured to respectively accommodate the second heating portions of the heating structure;
wherein each of the first accommodation areas is located between two adjacent ones of the first electrode structure layers and between two adjacent ones of the first insulating covering layers for accommodating a corresponding one of the first heating portions;
wherein each of the second accommodation areas is located between the first electrode structure layer and the second electrode structure layer which are adjacent to each other and between the first insulating covering layer and the second insulating covering layer which are adjacent to each other for accommodating a corresponding one of the second heating portions;
wherein the heating structure further includes a plurality of first connection portions and a plurality of second connection portions, each of the first connection portions is electrically connected between two adjacent ones of the first heating portions, and each of the second connection portions is electrically connected between the first heating portion and the second heating portion which are adjacent to each other;
wherein each of the first heating portions of the heating structure is configured to cooperate with the two adjacent first exposed end portions of two corresponding ones of the first electrode structure layers to form a first micro heater;
wherein each of the second heating portions of the heating structure is configured to cooperate with the first exposed end portion of a corresponding one of the first electrode structure layers and the second exposed end portion of a corresponding one of the second electrode structure layers to form a second micro heater.
